(19) United States
(12) Patent Application Publication
(10) Pub. No.: US 2026/0255957 A1
(43) Pub. Date: Aug. 27, 2026

(54) HEAT SINK STRUCTURE AND SEMICONDUCTOR PACKAGE COMBINED WITH THE HEAT SINK

(71) Applicant: JMJ Korea Co., Ltd., Busan (KR)

(72) Inventors: Yunhwa CHOI, Busan (KR); Jeongwoo CHOI, Busan (KR); Junho LEE, Busan (KR)

(73) Assignee: JMJ Korea Co., Ltd., Busan (KR)

(21) Appl. No.: 19/357,034

(22) Filed: Oct. 13, 2025

(30) Foreign Application Priority Data
Feb. 24, 2025 (KR) 10-2025-0023390

(51) Int. Cl. H01L 23/367; H01L 23/00; H01L 23/495

(52) U.S. Cl. CPC H10W 40/226; H10W 70/417; H10W 70/461; H10W 90/811; H10W 90/736

(57) ABSTRACT

Provided is a heat sink structure and a semiconductor package combined with the heat sink, and more particularly, to a heat sink structure having an improved structure to efficiently release heat generated from a semiconductor package through various surfaces of the semiconductor package and a semiconductor package combined with the heat sink structure. The heat sink structure according to an embodiment of the present invention includes two or more heat sinks that contact a first surface and a second surface of a semiconductor package to transmit heat. Each heat sink may include a first radiation unit including a first area having a flat surface contacting one surface of the semiconductor package and a third area having a length corresponding to the first area at the opposite sides of the first area; and a second radiation unit including a second area extended from the first area along a longitudinal direction of the semiconductor package and a fourth area having a length corresponding to the second area at the opposite sides of the second area, wherein the second area through the fourth area may include a plurality of radiation fins to expand a surface area contacting cooling air.

### CROSS-REFERENCE TO RELATED PATENT APPLICATION

This application claims the benefit of Korean Patent Application No. 10-2025-0023390, filed on Feb. 24, 2025, in the Korean Intellectual Property Office, the disclosure of which is incorporated herein in its entirety by reference.

### BACKGROUND OF THE INVENTION

### 1. Field of the Invention

The present invention relates to a heat sink structure and a semiconductor package combined with the heat sink, and more particularly, to a heat sink structure having an improved structure to efficiently release heat generated from a semiconductor package through various surfaces of the semiconductor package and a semiconductor package combined with the heat sink.

### 2. Description of the Related Art

Semiconductors are developed in such a way that more circuits are integrated into chip dies due to a line width downsizing work. When a size of a circuit decreases, higher performance may be shown at the same power consumption and lower power consumption may be used at the same performance level.

Meanwhile, the more a line width is downsized, the more power is consumed due to an expansion of resistance values to connection roads between elements and leakage current, and an exothermic phenomenon gets worse.

In general, a semiconductor package is used after one or more semiconductor chips are mounted onto a lead frame pad and are sealed with a bonding resin to protect the inside, and is installed in a printed circuit board. Since high-temperature heat generated from the inside of a package affects durability and operation of electronic products, heat radiation of a high-density package is important to ensure its performance.

When a semiconductor circuit is designed, it may be designed for temperature raised by heat to secure reliability on operation of a circuit up to a certain temperature. However, when a temperature increases above a certain temperature, reliability on operation of a circuit inside a chip may not be secured.

Accordingly, in order to prevent a semiconductor package from operational degradation occurring due to heat generation, a semiconductor package applied to a high power application field may include a heat sink or a cooling system to radiate heat and thereby, operational performance may be maintained.

A cooling system in which a fan is attached to a semiconductor package has excellent heat radiation effect, however, is expensive. In this regard, a semiconductor package including a heat sink may be widely used.

Accordingly, there is a demand for the technology that may facilitate combining a heat sink with a semiconductor package and maximize heat radiation effect through structural improvement of a heat sink.

### SUMMARY OF THE INVENTION

The present invention provides a heat sink structure and a semiconductor package combined with the heat sink in which the heat sink may thermally connect to various surfaces of the semiconductor package and thereby, heat from the semiconductor package may be rapidly and efficiently radiated.

The present invention also provides a heat sink structure and a semiconductor package combined with the heat sink in which the semiconductor package is accommodated on the heat sink by using a plurality of radiation fins so that a heat radiation space of the semiconductor package may be expanded and the accommodated semiconductor package may be protected.

The present invention also provides a heat sink structure and a semiconductor package combined with the heat sink in which a first radiation unit and a second radiation unit are included in the heat sink and heat radiation effect of the semiconductor package may be maximized through a structural design of radiation fins formed in each radiation unit.

According to an aspect of the present invention, there is provided heat sink structure including two or more heat sinks that contact a first surface and a second surface of a semiconductor package to transmit heat, each heat sink including: a first radiation unit including a first area having a flat surface contacting one surface of the semiconductor package and a third area having a length corresponding to the first area at the opposite sides of the first area; and a second radiation unit including a second area extended from the first area along a longitudinal direction of the semiconductor package and a fourth area having a length corresponding to the second area at the opposite sides of the second area, wherein the second area through the fourth area may include a plurality of radiation fins to expand a surface area contacting cooling air.

In an embodiment of the present invention, the distance between the plurality of radiation fins formed in the third area may be less than the distance between the plurality of radiation fins formed in the fourth area.

In an embodiment of the present invention, the heat sinks may include one or more projection units combined with a printed circuit board.

In an embodiment of the present invention, the projection units of the heat sinks may contact a radiation pattern of the printed circuit board.

In an embodiment of the present invention, the first area may include projection units combined to a partially etched area of a package housing included in the semiconductor package.

In an embodiment of the present invention, the length of the second area may be 0.2 through 0.5 times the length of the first area.

In an embodiment of the present invention, the plurality of radiation fins formed in the second area through the fourth area may be inclined by a predetermined angle with respect to a longitudinal direction of the semiconductor package.

In an embodiment of the present invention, the plurality of radiation fins formed in the second area through the fourth area may have a vertical structure with respect to a longitudinal direction of the semiconductor package.

In an embodiment of the present invention, the plurality of radiation fins formed in the second area and the plurality of radiation fins formed in the fourth area may correspond to each other.

In an embodiment of the present invention, the plurality of radiation fins of the second area in each heat sink may include a predetermined distance so as not to touch each other.

In an embodiment of the present invention, the thickness of the first radiation unit may be relatively greater than the thickness of the second radiation unit.

In an embodiment of the present invention, each heat sink may be spaced apart from the printed circuit board by a predetermined distance.

In an embodiment of the present invention, the distance between the plurality of radiation fins in the third area may be greater than the thickness of the plurality of radiation fins in the third area by more than two times.

In an embodiment of the present invention, the distance between the plurality of radiation fins in the third area may be less than the thickness of the first radiation unit.

In an embodiment of the present invention, the thickness of the plurality of radiation fins formed in the third area and the fourth area is thinner along the direction from the third area toward the fourth area.

In an embodiment of the present invention, a part of the radiation fins formed in second area may contact a third surface of the semiconductor package.

In an embodiment of the present invention, a predetermined part of the third area may have a flat surface where the radiation fins are removed.

According to another aspect of the present invention, there is provided semiconductor package combined with two or more heat sinks that contact a first surface and a second surface of a semiconductor package to transmit heat, the semiconductor package including: lead frames; semiconductor chips bonded onto a part of the lead frames by using conductive adhesives; a clip connected to the semiconductor chips; and a package housing that surrounds the lead frames, the semiconductor chips, and the clips, wherein each heat sink comprises: a first radiation unit including a first area having a flat surface contacting one surface of the semiconductor package and a third area having a length corresponding to the first area at the opposite sides of the first area; and a second radiation unit including a second area extended from the first area along a longitudinal direction of the semiconductor package and a fourth area having a length corresponding to the second area at the opposite sides of the second area, and wherein the second area through the fourth area may include a plurality of radiation fins to expand a surface area contacting cooling air.

In an embodiment of the present invention, the package housing may be partially etched and thereby, the clip or the lead frame may be thermally or electrically connected to the heat sinks by using bonding materials, which transmit heat or electricity generated while a semiconductor device operates, as the medium.

In an embodiment of the present invention, the thermal conductivity of the bonding materials may be in the range of 20 through 300 W/m·K.

### BRIEF DESCRIPTION OF THE DRAWINGS

The above and other features and advantages of the present invention will become more apparent by describing in detail exemplary embodiments thereof with reference to the attached drawings in which:

FIG. 1 is a perspective view of a semiconductor package combined with heat sinks according to an embodiment of the present invention;

FIG. 2 is a front view of the semiconductor package combined with the heat sinks of FIG. 1;

FIG. 3 is a front view illustrating the heat sinks and the semiconductor package of FIG. 1 separated from each other;

FIG. 4 is a front view of heat sinks according to another embodiment of the present invention;

FIG. 5 is a perspective view illustrating a semiconductor package and a printed circuit board combined with each other according to an embodiment of the present invention;

FIG. 6 is a cross-sectional view of a semiconductor package combined with heat sinks according to another embodiment of the present invention;

FIG. 7 is a front view illustrating a structure of a semiconductor package combined with heat sinks according to another embodiment of the present invention;

FIG. 8 is a front view illustrating a structure of a semiconductor package combined with heat sinks according to another embodiment of the present invention; and

FIG. 9 is a front view illustrating a structure of a semiconductor package combined with heat sinks according to another embodiment of the present invention.

### DETAILED DESCRIPTION OF THE INVENTION

Hereinafter, embodiments of the present invention will be described in more detail with reference to the accompanying drawings. In the drawings, like reference numerals denote like elements. Also, in the description, the detailed descriptions of well-known technologies and structures may be omitted so as not to hinder the understanding of the present invention.

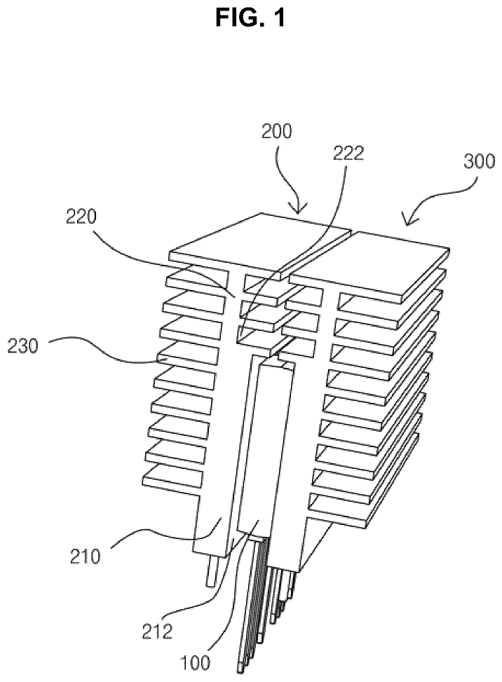

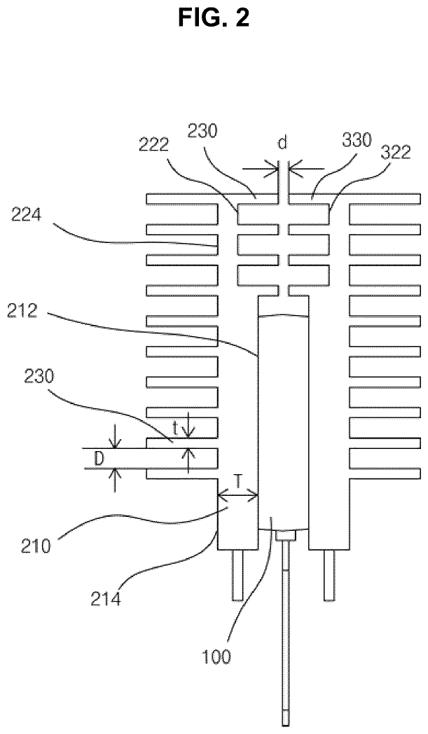

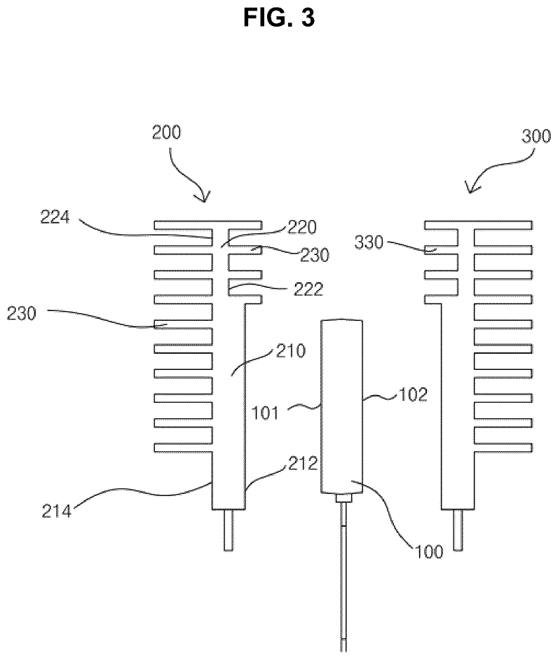

FIG. 1 is a perspective view of a semiconductor package combined with heat sinks according to an embodiment of the present invention, FIG. 2 is a front view of the semiconductor package combined with the heat sinks of FIG. 1, and FIG. 3 is a front view illustrating the heat sinks and the semiconductor package of FIG. 1 separated from each other.

Referring to FIGS. 1 through 3, a heat sink structure includes two heat sinks 200 and 300, each of which may contact a first surface 101 and a second surface 102 included in a semiconductor package 100 and thereby, may transmit heat.

The first surface 101 and the second surface 102 included in the semiconductor package 100 may be flat and their corresponding surfaces included in the heat sinks 200 and 300 may be also flat so that a heat contact area may be expanded.

The heat sinks 200 and 300 disposed at both surfaces of the semiconductor package 100 may be symmetric to each other. Hereinafter, for convenience of description, one heat sink 200 is mainly described, however, the other heat sink 300 may have the same or similar structure.

The heat sink 200 may include a first radiation unit 210 and a second radiation unit 220, wherein the first radiation unit 210 may include a first area 212 and a third area 214 and the second radiation unit 220 may include a second area 222 and a fourth area 224.

The first area 212 of the heat sink 200 may have the flat surface contacting one surface of the semiconductor package 100. As the first area 212 is a surface directly contacting the semiconductor package 100, the first area 212 may be formed to entirely contact one surface of the semiconductor package 100 so as to rapidly transmit heat generated from the semiconductor package 100.

The second area 222 of the heat sink 200 may be extended from the first area 212 along a longitudinal direction of the semiconductor package 100 and the total length of the first area 212 and the second area 222 may be greater than the length of the semiconductor package 100.

The third area 214 and the fourth area 224 of the heat sink 200 may have the lengths each corresponding to the first area 212 and the second area 222 at the opposite sides of the first area 212 and the second area 222.

The second area 222 through the fourth area 224 of the heat sink 200 may include a plurality of radiation fins 230. A surface area contacting cooling air may be expanded by the plurality of radiation fins 230 and the heat sink 200 may have an air-cooled structure in which the heated radiation fins 230 are cooled by air flow.

For high heat conductivity, the heat sink 200 may be formed of a solder containing Sn, a single material such as Al, Cu, or ceramic, or a composite material containing 50% or more of any one of Sn, Al, Cu, and ceramic.

The heat sink 200 may be formed of a nonconductive material or a conductive material containing 50% or more of metal components and may be in the form of paste so that the heat sink 200 may have the structural form by being cured and hardened at a high temperature of 100° C. or above.

According to an embodiment of the present invention, the length of the second area 222 included in the heat sink 200 may be 0.2 through 0.5 times the length of the first area 212.

The semiconductor package 100 may be combined by being accommodated on the heat sink 200 by the plurality of radiation fins 230 formed in the second area 222 of the heat sink 200 and the total length of the heat sink 200 may be greater than the length of the semiconductor package 100 so that an area contacting cooling air may be expanded and thereby, the heat radiation effect by the heat sink 200 may be maximized.

The second area 222 of the heat sink 200 is disposed beyond the length of the semiconductor package 100. Accordingly, when the second area 222 of the heat sink 200 is formed too long, downsizing of the semiconductor package 100 may be hardly available. In this regard, the length of the second area 222 of the heat sink 200 may be formed to be below 0.5 times the length of the first area 212.

Also, the second area 222 of the heat sink 200 is designed to maximize the heat radiation effect so that the length of the second area 222 of the heat sink 200 may be formed to be above 0.2 times the length of the first area 212.

The thickness of the first radiation unit 210 of the heat sink 200 may be formed to be relatively greater than the thickness of the second radiation unit 220.

The first area 212 of the heat sink 200 directly contacts the semiconductor package 100. Since heat generated from the semiconductor package 100 is transmitted relatively a lot between the first area 212 and the third area 214, the thickness of the first radiation unit 210 of the heat sink 200 may be formed to be relatively greater than the thickness of the second radiation unit 220.

Heat from the semiconductor package 100 transmitted to the first area 212 of the first radiation unit 210 may be transmitted along an arbitrary direction. Here a part of the heat may be released by cooling air through the plurality of radiation fins 230 formed in the third area 214 disposed close to the first area 212 and the rest may be transmitted toward the second radiation unit 220.

The heat transmitted to the second radiation unit 220 may be partially released by cooling air through the plurality of radiation fins 230 formed in the second area 222 and the fourth area 224.

According to the structure of the heat sink 200, the amount of heat transmitted to the second radiation unit 220 may be relatively lower than the amount of heat transmitted to the first radiation unit 210. When the thickness of the second radiation unit 220 is formed to be less than that of the first radiation unit 210, downsizing and weight reduction of the heat sink 200 itself may be available.

In the second radiation unit 220, the plurality of radiation fins 230 formed in the second area 222 and the plurality of radiation fins 230 formed in the fourth area 224 may be disposed to correspond to each other.

Heat transmitted from the first radiation unit 210 may be transmitted along a longitudinal direction of the second radiation unit 220. Here, the heat transmitted along a longitudinal direction moves to both direction through the plurality of radiation fins 230 formed to correspond to the second area 222 and the fourth area 224 so that areas to which the heat may simultaneously move may be expanded and thereby, it may be an advantage in terms of the heat radiation effect.

Also, when the plurality of radiation fins 230 formed in the second area 222 and the plurality of radiation fins 230 formed in the fourth area 224 may be disposed to correspond to each other in the second radiation unit 220, its symmetrical form is structurally simple and thereby, difficulties and unit costs in manufacturing may be lowered.

The plurality of radiation fins 230 and 330 of the second areas 222 and 322 included in each heat sink 200 and 300 disposed at the upper part of the semiconductor package 100 may include a predetermined distance d so as not to touch each other.

Cooling air from the outside flows between the pluralities of radiation fins 230 and 330. When the pluralities of radiation fins 230 and 330 of the second areas 222 and 322 included in the heat sinks 200 and 300 disposed at left and right sides in FIG. 2 touch each other, a space through which cooling air moves narrows so that cooling air may not smoothly flow and thereby, the heat radiation effect may be lowered.

On the other hand, when the predetermined distance d is formed between the pluralities of radiation fins 230 and 330 of the second areas 222 and 322 included in the heat sinks 200 and 300 disposed at left and right sides in FIG. 2, a space through which cooling air moves upward and downward of the pluralities of radiation fins 230 and 330 may be additionally secured and minute turbulent flow may be formed in cooling air by the predetermined distance d disposed between the pluralities of radiation fins 230 and 330. Accordingly, heat radiation may be facilitated through the front ends of the pluralities of radiation fins 230 and 330.

According to an embodiment of the present invention, a distance D between the plurality of radiation fins 230 of the third area 214 may be less than the thickness T of the first radiation unit 210.

Heat radiated from the semiconductor package 100 is directly transmitted through the first area 212 of the first radiation unit 210 and then, may be transmitted to an arbitrary direction.

In consideration of the time that heat transmission is accomplished between the first area 212 and the third area 214 in the first radiation unit 210 and the heat contact areas, the distance D between the plurality of radiation fins 230 of the third area 214 may be formed to be less than the thickness T of the first radiation unit 210, that is, the distance between the first area 212 and the third area 214 in the first radiation unit 210. In this case, the surface area contacted by cooling air between the plurality of radiation fins 230 may be expanded and thereby, the heat radiation effect by cooling air may be increased.

According to an embodiment of the present invention, the distance D between the plurality of radiation fins 230 of the third area 214 included in the first radiation unit 210 may be greater than the thickness t of the plurality of radiation fins 230 of the third area 214 by more than two times.

The amount of heat transmitted from the first area 212 to the third area 214 is temporarily received to the plurality of radiation fins 230 formed in the third area 214 and at the same time, heat is radiated by cooling air flowing between the plurality of radiation fins 230.

In consideration of the amount of heat temporarily received to the plurality of radiation fins 230 formed in the third area 214 and the amount of cooling air flowing through a space between the plurality of radiation fins 230, an appropriate amount of cooling air may flow through a space between the plurality of radiation fins 230 to make heat exchange with the plurality of radiation fins 230.

In the present invention, the distance D between the plurality of radiation fins 230 of the third area 214 included in the first radiation unit 210 is formed to be greater than the thickness t of the plurality of radiation fins 230 of the third area 214 by more than two times and thereby, heat exchange between cooling air and the plurality of radiation fins 230 may be maximized.

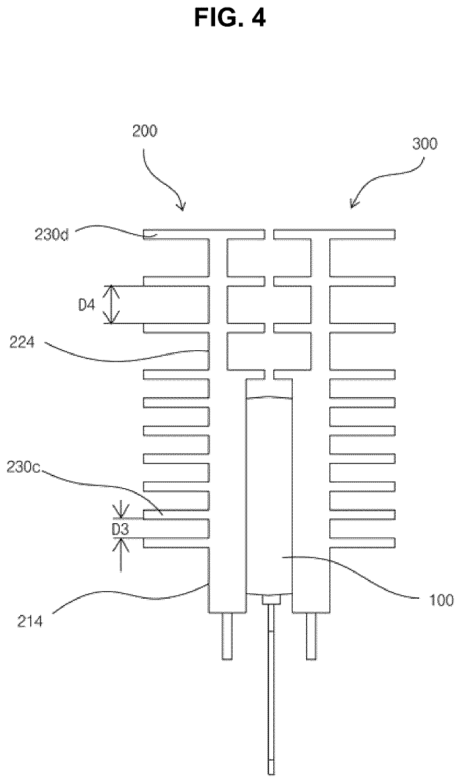

FIG. 4 is a front view of the heat sinks 200 and 300 according to another embodiment of the present invention.

Referring to FIG. 4, a distance D3 between a plurality of radiation fins 230c formed in the third area 214 of the heat sink 200 may be relatively less than a distance D4 between a plurality of radiation fins 230d formed in the fourth area 224.

Since the plurality of radiation fins 230c of the third area 214 is disposed relatively closer to the semiconductor package 100 than the plurality of radiation fins 230d of the fourth area 224, a distance between the plurality of radiation fins 230c of the third area 214 may be designed to be dense so that heat radiated from the semiconductor package 100 may be transmitted to more radiation fins 230c.

Here, when the distance between the plurality of radiation fins 230 is too dense, cooling air may be prevented from flowing so that the distance between the plurality of radiation fins 230 may be adjusted according to density or viscosity of cooling air.

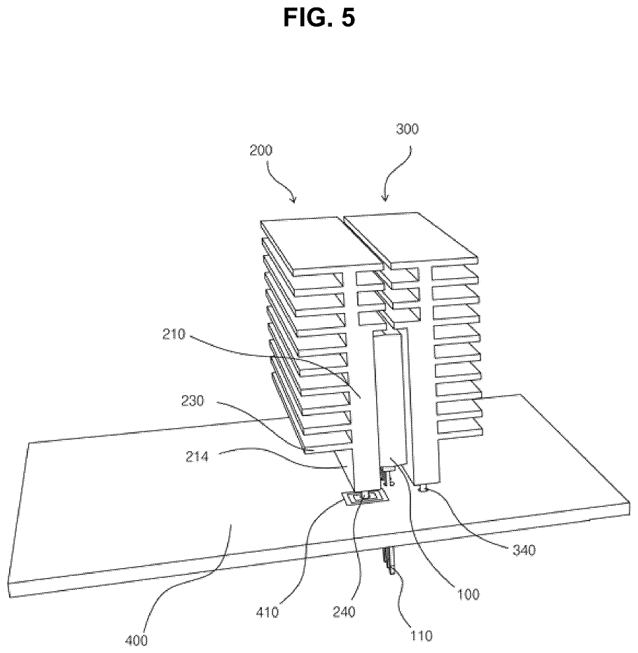

FIG. 5 is a perspective view illustrating the semiconductor package 100 and a printed circuit board 400 combined with each other according to an embodiment of the present invention.

Referring to FIG. 5, the heat sinks 200 and 300 are combined to both surfaces of the semiconductor package 100, wherein the heat sinks 200 and 300 may include one or more projection units 240 and 340 contacting the printed circuit board 400.

The semiconductor package 100 may be supported by a lead frame lead 110 in such a way that the lead frame lead 110 penetrates the printed circuit board 400. When the projection units 240 and 340 are formed on the heat sinks 200 and 300, the weights of the heat sinks 200 and 300 and the semiconductor package 100 are dispersed by the projection units 240 and 340 so that the heat sinks 200 and 300 and the semiconductor package 100 may be stably supported and heat radiated from the semiconductor package 100 may be partially transmitted to the printed circuit board 400 through the projection units 240 and 340. Accordingly, it may be an advantage in terms of the heat radiation effect.

The number and position of the projection units 240 and 340 formed on the heat sinks 200 and 300 are not particularly restricted and the projection units 240 and 340 of the heat sinks 200 and 300 are formed to contact a radiation pattern 410 of the printed circuit board 400 so that the heat radiation effect of the semiconductor package 100 may be increased.

According to an embodiment of the present invention, a predetermined part of the third area 214 in a first radiation unit 210 may have a flat surface where the radiation fins 230 are removed. In this regard, the predetermined part of the third area 214 in the heat sink 200 may be designed to be flat in advance and then, is formed as one body with the radiation fins 230. Also, the heat sink 200 may be manufactured in such a way that the radiation fins 230 are formed on the entire surface of the third area 214 and then, a part of the radiation fins 230 is removed to make a flat surface.

A plurality of elements are combined onto the printed circuit board 400. When the radiation fins 230 are removed from a predetermined part of the third area 214 of the heat sink 200, a space available for other elements to be placed is made to the corresponding part so as to facilitate an arrangement of elements installed on the printed circuit board 400 and to form entire components to be compact.

According to another embodiment of the present invention, each heat sink 200 and 300 may be spaced apart from the printed circuit board 400 by a predetermined distance and may not include the projection units 240 and 340.

When a plurality of the semiconductor packages 100 is combined onto the printed circuit board 400 and thereby, heat transmitted to the printed circuit board 400 interrupts the performance of the printed circuit board 400, each of the heat sinks 200 and 300 is disposed and spaced apart from the printed circuit board 400 by a predetermined distance to relieve thermal burden of the printed circuit board 400 so that heat may be prevented from being directly transmitted to the printed circuit board 400 from the heat sinks 200 and 300 and thereby, the printed circuit board 400 may be protected.

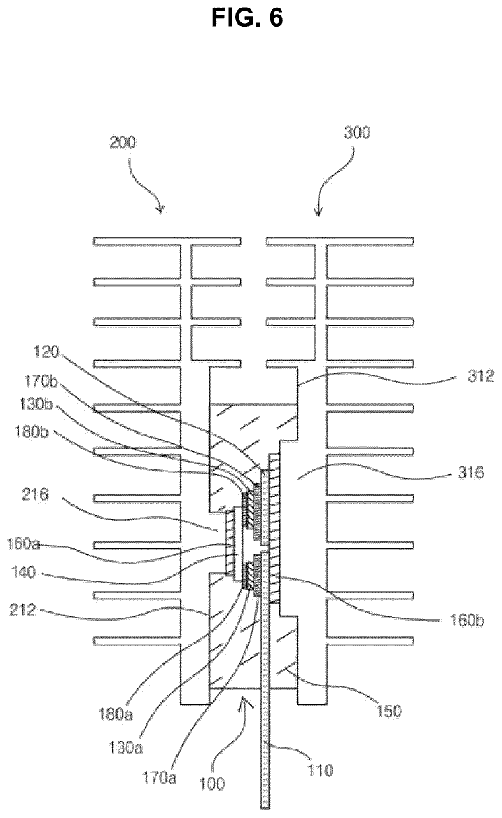

FIG. 6 is a cross-sectional view of the semiconductor package 100 combined with the heat sinks 200 and 300 according to another embodiment of the present invention.

Referring to FIG. 6, the semiconductor package 100 may include the lead frame lead 110, a lead frame pad 120, semiconductor chips 130a and 130b, and a clip 140 which are surrounded by a package housing 150.

The package housing 150 of the semiconductor package 100 may be partially etched up to the depth reaching the surface of the clip 140 or the lead frames 110 and 120.

Projection units 216 and 316 projected from first areas 212 and 312 of the heat sinks 200 and 300 are combined to a partially etched area of the package housing 150 in the semiconductor package 100 and thus, the projection units 216 and 316 of the heat sinks 200 and 300 may be thermally or electrically connected to clip 140 or the lead frames 110 and 120 by using bonding materials 160a and 160b as a medium.

The bonding materials 160a and 160b are layers having excellent adhesive strength and thermal conductivity on the clips 140 or interposed between the lead frames 110 and 120 and the heat sinks 200 and 300 and may include silica or alumina powder for increasing thermal conductivity.

The thermal conductivity of the bonding materials 160a and 160b may be in the range of 20 through 300 W/m·K. In this range, the adhesive strength of the heat sinks 200 and 300 and the semiconductor package 100 may be effectively maintained and heat or electricity generated from semiconductor devices may be stably transmitted to the heat sinks 200 and 300.

Since the etched areas of the projection units 216 and 316 in the heat sinks 200 and 300 and the semiconductor package 100 are prepared, positions to which the heat sinks 200 and 300 and the semiconductor package 100 are combined may be precisely designed in advance. Also, since the projection units 216 and 316 of the heat sinks 200 and 300 are combined to the etched areas of the package housing 150, combination of the heat sinks 200 and 300 to the package housing 150 may be more stable and heat inside the semiconductor package 100 may be effectively released to the outside.

The lead frame may include the lead frame lead 110 and the lead frame pad 120, wherein the lead frame pad 120 may include one surface including a metal pattern formed thereon and the lead frame lead 110 may be electrically connected to the semiconductor chips 130a and 130b by using conductive adhesives 170a and 170b so as to transmit an electric signal to the outside of the package housing 150.

The lead frame lead 110 and the lead frame pad 120 may be formed of a material containing 90% or more of Cu or a material containing 50% or more of Al. Also, at least one lead frame lead 110 or at least one lead frame pad 120 may have a stack structure in which at least a part of a main metal layer is coated with one or more sub-metal layers.

The lead frame lead 110 and the lead frame pad 120 may be thermally or electrically connected to the heat sinks 200 and 300 by using the bonding materials 160a and 160b as the medium.

One or more semiconductor chips 130a and 130b may be included to be bonded onto the lead frame lead 110 or the lead frame pad 120 by using, for example, the conductive adhesives 170a and 170b interposed therebetween such as solders. The adhesives, however, may not be limited to those embodiments, include insulating adhesives such as epoxy adhesives or insulating tapes.

The semiconductor chips 130a and 130b may include semiconductor devices, wherein the semiconductor devices may include semiconductor materials such as silicon and may be vertical or horizontal devices.

The vertical devices may include at least one input unit at one part of the semiconductor chips 130a and 130b and an output unit at the other part of the semiconductor chips 130a and 130b so that current may flow vertically through chips.

The horizontal devices may include at least one input unit at least one part of the semiconductor chips 130a and 130b and at least one output unit at the same part of the semiconductor chips 130a and 130b so that current may flow horizontally through the semiconductor chips 130a and 130b.

The semiconductor devices included in the semiconductor chips 130a and 130b may include various semiconductor devices, for example, power semiconductor devices such as diodes, transistors, thyristor, or IGBT, linear devices, integrated circuits, and logic circuits.

As illustrated in the drawing, the semiconductor chips 130a and 130b may be electrically connected to the lead frames 110 and 120 or the clip 140 through conductive adhesives 170a, 170b, 180a, and 180b.

The semiconductor chips 130a and 130b may be MOSFET, IGBT, or power conversion semiconductor devices including GaN devices, SiC devices, or Ga devices and may be applied to devices such as inverters, converters, or On Board Chargers (OBC) which convert or control power. Since excessive heat is generated while the semiconductor chips 130a and 130b convert power into power having a specific current, a specific voltage, or a specific frequency, heat may be released through the heat sinks 200 and 300.

The clip 140 may be used to electrically connect one or more semiconductor chips 130a and 130b and may be formed of a single material including any one of Au, Ag, Al, and Cu or an alloy containing 50 weight % or more of any one of Au, Ag, Al, and Cu. The clip 140 and the semiconductor chips 130a and 130b and may be electrically connected to each other by using the conductive adhesives 180a and 180b interposed therebetween.

The package housing 150 is a structure for protecting semiconductor circuits that surround a part of the lead frame lead 110, the lead frame pad 120, the semiconductor chips 130a and 130b, and the clip 140 and may be formed of an Epoxy Molding Compound (EMC), PolyPhenylene Sulfide (PPS), or PolyButylene Terephtalate (PBT) or a composite material such as PolyPhenylene Sulfide (PPS) or PolyButylene Terephtalate (PBT) instead of epoxy-based material.

The bonding materials 160a and 160b may be formed of a single material such as Ag, Au, Cu, Ti, Ni, or Pd or a composite material containing 50% or more of any one of Ag, Au, Cu, Ti, Ni, and Pd.

The bonding materials 160a and 160b may be coated on the etched area of the package housing 150 so as to absorb stress which may be transmitted to the semiconductor chips 130a and 130b and may facilitate a bonding work of the heat sinks 200 and 300.

For example, the bonding materials 160a and 160b may contain 10% or more of Sn and may be formed between the clip 140, the lead frame pad 120, or at least a part of the lead frame lead 110, each of which is included in the package housing 150, and the heat sinks 200 and 300 by a predetermined thickness. Also, the bonding materials 160a and 160b may be formed of an insulating material or a dielectric material and may be formed between the clip 140, the lead frame pad 120, or at least a part of the lead frame lead 110, each of which is included in the package housing 150, and the heat sinks 200 and 300 by a predetermined thickness. Moreover, the bonding materials 160a and 160b may be formed of grease and may be formed between the clip 140, the lead frame pad 120, or at least a part of the lead frame lead 110, each of which is included in the package housing 150, and the heat sinks 200 and 300 by a predetermined thickness.

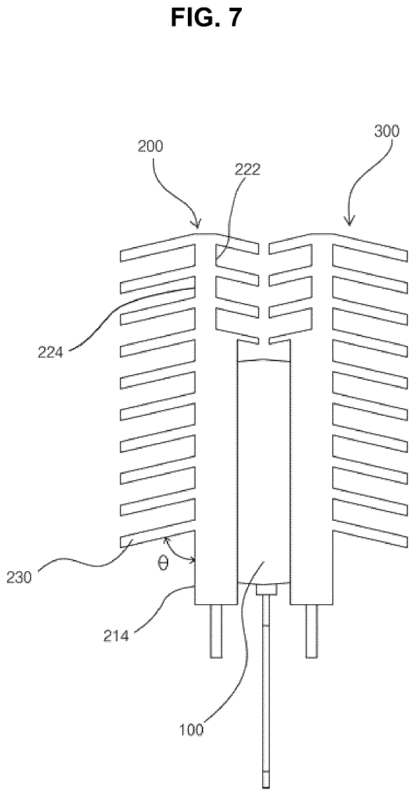

FIG. 7 is a front view illustrating a structure of the semiconductor package 100 combined with the heat sinks 200 and 300 according to another embodiment of the present invention.

Referring to FIG. 7, the plurality of radiation fins 230 formed in the second area 222 through the fourth area 224 of the heat sink 200 may be inclined by a predetermined angle θ with respect to a longitudinal direction of the semiconductor package 100.

A plurality of semiconductor packages 100 may be combined onto the printed circuit board 400 and the plurality of radiation fins 230 may be formed to be inclined by a predetermined angle θ with respect to a longitudinal direction of the semiconductor package 100 for preventing interference with the adjacent semiconductor package 100 and for structural efficiency.

Meanwhile, as illustrated in FIGS. 1 through 3, the plurality of radiation fins 230 formed in the second area 222 through the fourth area 224 of the heat sink 200 may have a vertical structure with respect to a longitudinal direction of the semiconductor package 100.

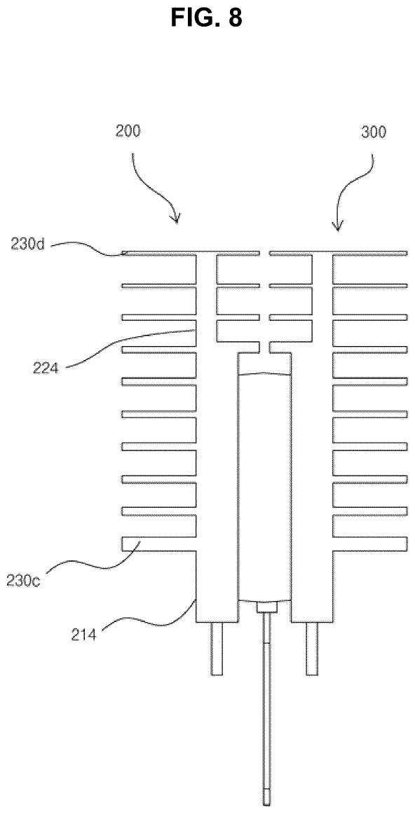

FIG. 8 is a front view illustrating a structure of the semiconductor package 100 combined with the heat sinks 200 and 300 according to another embodiment of the present invention.

Referring to FIG. 8, the thickness of the plurality of radiation fins 230c and 230d formed in the third area 214 and the fourth area 224 of the heat sink 200 may be thinner along the direction from the third area 214 toward the fourth area 224.

The plurality of radiation fins 230c formed in the third area 214 of the heat sink 200 is relatively closer to the semiconductor package 100 which radiates heat so that heat transmitted from the semiconductor package 100 is excessive and thereby, the radiation fins 230c may relatively have a great thickness in order to temporarily receive heat and to radiate heat through cooling air.

Since a heat transmission path from the semiconductor package 100 lengthens along the direction from the third area 214 toward the fourth area 224 in the heat sink 200 and heat radiation is accomplished by cooling air during the transmission path, the amount of transmitted heat decreases toward the fourth area 224 and the thickness of the plurality of radiation fins 230d formed in the fourth area 224 may be relatively thin.

In another embodiment, the plurality of radiation fins 230c formed in the third area 214 may have the same thicknesses and the plurality of radiation fins 230d formed in the fourth area 224 may have the same thicknesses. However, the thicknesses of the plurality of radiation fins 230c formed in the third area 214 may be greater than the thicknesses of plurality of radiation fins 230d formed in the fourth area 224.

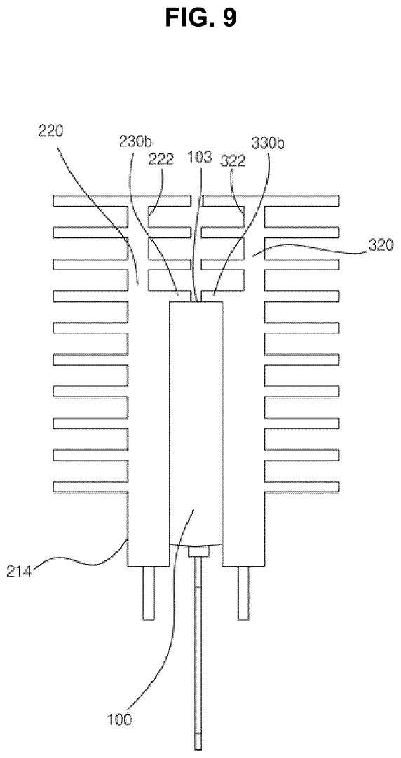

FIG. 9 is a front view illustrating a structure of the semiconductor package 100 combined with the heat sinks 200 and 300 according to another embodiment of the present invention.

Referring to FIG. 9, a part of radiation fins 230b and 330b formed in second areas 222 and 322 of second radiation units 220 and 320 may contact a third surface 103 of the semiconductor package 100.

More specifically, from among the plurality of radiation fins 230b and 330b of the second radiation units 220 and 320, the radiation fins 230b and 330b facing the semiconductor package 100 may contact the third surface 103 of the semiconductor package 100 and heat released through the third surface 103 may be directly transmitted to the second radiation units 220 and 320.

Accordingly, a contact area between the heat sinks 200 and 300 and the semiconductor package 100 that generates heat is expanded and thereby, heat release from the semiconductor package 100 may be accelerated through the heat sinks 200 and 300.

In the semiconductor package combined with the heat sink structure and the heat sinks according to the present invention, the heat sinks are thermally connected to various surfaces of the semiconductor package so that heat of the semiconductor package may be rapidly and efficiently released.

Also, in the semiconductor package combined with the heat sink structure and the heat sinks according to the present invention, the semiconductor package is accommodated on the heat sinks by using the plurality of radiation fins so that a heat release space of the semiconductor package may be expanded and the accommodated semiconductor package may be protected.

Moreover, in the semiconductor package combined with the heat sink structure and the heat sinks according to the present invention, the heat sinks include the first radiation unit and the second radiation unit so that heat radiation of the semiconductor package may be maximized through a structure design of the radiation fins formed in each radiation unit.

The present invention has been particularly shown and described with reference to exemplary embodiments thereof, however, may not be limited to those embodiments. For example, the number of radiation fins formed in the heat sinks are not restricted to those illustrated in the drawings. Also, it will be understood by those of ordinary skill in the art that various changes in form and details may be made therein without departing from the spirit and scope of the present invention as defined by the following claims.

What is claimed is:

1. A heat sink structure comprising two or more heat sinks that contact a first surface and a second surface of a semiconductor package to transmit heat, each heat sink comprising:
a first radiation unit comprising a first area having a flat surface contacting one surface of the semiconductor package and a third area having a length corresponding to the first area at the opposite sides of the first area; and
a second radiation unit comprising a second area extended from the first area along a longitudinal direction of the semiconductor package and a fourth area having a length corresponding to the second area at the opposite sides of the second area,
wherein the second area through the fourth area comprise a plurality of radiation fins to expand a surface area contacting cooling air.

2. The heat sink structure of claim 1, wherein the distance between the plurality of radiation fins formed in the third area is less than the distance between the plurality of radiation fins formed in the fourth area.

3. The heat sink structure of claim 1, wherein the heat sinks comprise one or more projection units combined with a printed circuit board.

4. The heat sink structure of claim 3, wherein the projection units of the heat sinks contact a radiation pattern of the printed circuit board.

5. The heat sink structure of claim 1, wherein the first area comprises projection units combined to a partially etched area of a package housing included in the semiconductor package.

6. The heat sink structure of claim 1, wherein the length of the second area is 0.2 through 0.5 times the length of the first area.

7. The heat sink structure of claim 1, wherein the plurality of radiation fins formed in the second area through the fourth area is inclined by a predetermined angle with respect to a longitudinal direction of the semiconductor package.

8. The heat sink structure of claim 7, wherein the plurality of radiation fins formed in the second area through the fourth area has a vertical structure with respect to a longitudinal direction of the semiconductor package.

9. The heat sink structure of claim 1, wherein the plurality of radiation fins formed in the second area and the plurality of radiation fins formed in the fourth area correspond to each other.

10. The heat sink structure of claim 1, wherein the plurality of radiation fins of the second area in each heat sink comprises a predetermined distance so as not to touch each other.

11. The heat sink structure of claim 1, wherein the thickness of the first radiation unit is relatively greater than the thickness of the second radiation unit.

12. The heat sink structure of claim 1, wherein each heat sink is spaced apart from the printed circuit board by a predetermined distance.

13. The heat sink structure of claim 1, wherein the distance between the plurality of radiation fins in the third area is greater than the thickness of the plurality of radiation fins in the third area by more than two times.

14. The heat sink structure of claim 1, wherein the distance between the plurality of radiation fins in the third area is less than the thickness of the first radiation unit.

15. The heat sink structure of claim 1, wherein the thickness of the plurality of radiation fins formed in the third area and the fourth area is thinner along the direction from the third area toward the fourth area.

16. The heat sink structure of claim 1, wherein a part of the radiation fins formed in second area contacts a third surface of the semiconductor package.

17. The heat sink structure of claim 1, wherein a predetermined part of the third area has a flat surface where the radiation fins are removed.

18. A semiconductor package combined with two or more heat sinks that contact
a first surface and a second surface of a semiconductor package to transmit heat, the semiconductor package comprising:
lead frames;
semiconductor chips bonded onto a part of the lead frames by using conductive adhesives;
a clip connected to the semiconductor chips; and
a package housing that surrounds the lead frames, the semiconductor chips, and the clips,
wherein each heat sink comprises: a first radiation unit comprising a first area having a flat surface contacting one surface of the semiconductor package and a third area having a length corresponding to the first area at the opposite sides of the first area; and a second radiation unit comprising a second area extended from the first area along a longitudinal direction of the semiconductor package and a fourth area having a length corresponding to the second area at the opposite sides of the second area, and wherein the second area through the fourth area comprise a plurality of radiation fins to expand a surface area contacting cooling air.

19. The semiconductor package of claim 18, wherein the package housing is partially etched and thereby, the clip or the lead frame is thermally or electrically connected to the heat sinks by using bonding materials, which transmit heat or electricity generated while a semiconductor device operates, as the medium.

20. The semiconductor package of claim 19, wherein the thermal conductivity of the bonding materials is in the range of 20 through 300 W/m·K.
